(19) United States
(12) Patent Application Publication
(10) Pub. No.: US 2025/0239442 A1
(43) Pub. Date: Jul. 24, 2025

(54) METHOD AND DEVICE FOR PROTECTING OXYGEN-SENSITIVE TARGET MATERIALS IN A COATING SOURCE

(71) Applicant: FHR ANLAGENBAU GMBH, Ottendorf-Okrilla (DE)

(72) Inventors: Sven HAEBERLEIN, Ottendorf-Okrilla (DE); Detlef SONTAG, Waldenburg (DE)

(73) Assignee: FHR ANLAGENBAU GMBH, Ottendorf-Okrilla (DE)

(21) Appl. No.: 18/849,306

(22) PCT Filed: Feb. 22, 2023
(86) PCT No.: PCT/EP2023/054346

§ 371 Date: Sep. 20, 2024

(30) Foreign Application Priority Data
Mar. 21, 2022 (DE) 10 2022 106 547.2
Nov. 3, 2022 (DE) 10 2022 129 017.4

(51) Int. Cl. H01J 37/34; C23C 14/00; H01J 37/32

(52) U.S. Cl. CPC H01J 37/3447; C23C 14/0036; H01J 37/32449; H01J 2237/332

(57) ABSTRACT

The invention discloses a method and a device for protecting oxygen-sensitive target materials in a coating source. The problem of specifying a method and arrangement, by means of which reactive, in particular oxygen-sensitive target materials of a coating source can be protected against contaminations and undesired reactions, is solved by a method in which first of all the shutter sealingly closes the coating source, and a protective gas is fed via a gas inlet into a coating source chamber which is formed by the coating source and the shutter. Here, a positive pressure is set in the coating source chamber with respect to a vacuum chamber pressure within the process chamber. Subsequently, a further gas for reacting with, that is to say neutralizing coatings in the process chamber, is fed into the process chamber. The process chamber is then ventilated with air or nitrogen, without an undesired reaction taking place. The process chamber is subsequently opened towards atmosphere, that is to say the door of the process chamber to the surrounding area is opened, wherein a positive pressure with respect to atmosphere is then constantly maintained in the coating source chamber.

The invention relates to a method and to an apparatus for protection of oxygen-sensitive target materials in a coating source.

Sputtering is a coating technique from the group of PVD (physical vapor deposition) methods. Sputtering, also called cathodic atomization, means a physical operation in which atoms are removed from a solid-state body, called the target, by bombardment with high-energy (noble gas) ions and are converted to the gas phase. Depending on the materials used and the layer properties and deposition rates envisaged, various sputtering methodologies are used.

In the field of coating technology, sputtering accordingly serves to atomize a material which is then deposited on a substrate and forms a solid layer. In order to achieve a defined layer thickness in the coating, especially the sputtering, of various materials onto a substrate, shutter systems are used in order to control the flow of material onto the substrates to be coated.

Sputtering takes place in a coating system under vacuum conditions. Depending on the sputtering variant used (DC sputtering, HF sputtering, magnetron sputtering, ion beam sputtering, reactive sputtering, inter alia), a voltage is applied between two electrodes and a working gas is admitted into the gas space. Impact ionization of the atoms of the working gas used, for example argon, forms a plasma in the gas space. The target usually forms the negative electrode, and the substrate to be coated usually forms the positively charged electrode. In the case of magnetron sputtering, there is an additional magnetic field behind the cathode. In the case of reactive sputtering, one or more reactive gases are added to the inert working gas (argon). The gases react at the target in the vacuum chamber or at the substrate with the atomized layer atoms and form new materials. In ion beam sputtering, a beam of noble gas sputtering ions (argon, krypton, xenon) is directed from an ion source onto the target—this results in atomization by the incident ion beam.

For a stable sputtering process, the coating system is switched on, i.e. the voltage is applied to the electrodes and the plasma is ignited and the desired operating power for a stable process is set and established. Only thereafter is the shutter opened in order to commence the coating of the substrates. The coating source is shielded beforehand by a shutter. In order to ensure the ignition of the plasma, a gap of a few millimeters must exist between coating source and shutter. Typically, the shutter is a metal sheet which is pivoted from the side in front of the coating source, such that no material unintentionally reaches the substrates to be coated from the coating source.

Any unwanted flow of material, called cross-contamination, onto the substrates and the environment of the coating source is most effectively prevented when the distance of the metal sheet from the coating source is very small and hence the coating source is optimally shielded from the substrates.

Especially in the case of arrangements of multiple coating sources within a coating chamber or process chamber, there can be mutual coating of the coating sources (targets) by cross-contamination if the coating sources cannot be completely sealed. As a result, it is often necessary to remove material from the contaminated targets again before the actual process of coating the substrates by sputtering, also called clear-sputtering, in order to maintain and to ensure the quality of the coating materials. This results in lowering both of the quality of coating and the exploitation of material, and also of the productivity of the coating arrangement.

The shutter sheets used have to date been inserted in front of the coating source at a distance of about 1 to 4 mm. However, this distance cannot ensure completely closed shielding of the coating source. But the distance is necessary for the initiation of sputtering of a coating source. Lower, i.e. smaller, distances cannot be implemented in practical execution since these typically lead to friction between the shutter sheet and coating source. These friction effects cause many unwanted particles that can lead to additional contamination of the coated substrates, which can also lead to detachment of the layers from the substrate. The quality of the layers can be significantly impaired by these effects.

WO 2021/091890 A1 discloses a shutter mechanism in which a shutter is connected to an actuator via a coupling mechanism such that the shutter can be moved in a composite movement from an open position to a closed position over a coating source. The actuator here merely performs a linear movement along a translation axis, with conversion of a linear movement of the shutter to a tilting movement via a curved groove and back to a concluding linear movement until the shutter encloses the sputtering source. The shutter firstly performs a linear movement along the translation axis of the actuator, then a rotary movement, for example by 90°, to the translation axis of the actuator, and finally a linear movement, again along the translation axis of the actuator. A disadvantage is that these movements cannot be controlled separately and independently from one another since, firstly, they are defined by the curved groove and, secondly, fine adjustment of the shutter by means of the actuator is possible only to a very limited degree. Especially in the case of use of a pneumatic actuator, persistence of the shutter in an intermediate position, for example for the initiation of sputtering or pre-sputtering processes, i.e. a few millimeters above the sputtering source, by the solution described in WO 2021/091890 A1, is not possible and reproducible only inaccurately without additional technical devices.

The fact that the axis of rotation of the shutter in the solution described in WO 2021/091890 A1 does not lie parallel to the longitudinal axis of the coating source means that it is also possible during the pivoting of the shutter between open and closed positions for there to be disadvantageous curvature of the gas plasma since there is a change in the angle between target surface and shutter surface. This can additionally result in unwanted coating of the inside of the chamber or the coating source itself.

It is likewise disadvantageous that the actuator in WO 2021/091890 A1 is disposed with the curved groove within the vacuum chamber. The mechanical stress exerted by the coupling system and the associated friction in the curved groove can result in abrasion, which is unwanted in a coating system with high purity demands. Maintenance and/or repair of the shutter actuator is thus also significantly more demanding since this can be effected only with ventilation of the vacuum chamber.

Even for the use of oxygen-sensitive target materials in a coating source (sputtering source), the use of conventional shutter systems is impossible. Especially for cleaning and maintenance operations, it is often necessary to open the vacuum or process chambers in which the coating sources are present. If oxygen-sensitive materials, for example lithium, are used, contact with oxygen can lead to chemical reaction with the target material, which makes the target material unusable and necessitates special safety measures. The gap between the shutter plate and coating source promotes the penetration of oxygen and should thus also be avoided for maintenance purposes.

It is therefore an object of the invention to specify both a method and an arrangement by means of which reactive, in particular oxygen-sensitive, target materials of a coating source can be protected from contamination.

The object is achieved by a method according to independent method claim 1. In the method for protection of a coating source comprising a reactive coating material, where the coating source comprising the coating material is shielded from a process chamber by a shutter, the shutter firstly closes off the coating source in a sealing manner and a protective gas is admitted via a gas inlet into a coating source space which is formed by the coating source and the shutter, and a positive pressure is established in the coating source space relative to a vacuum chamber pressure within the process chamber and also, later on, in the ventilation of the process chamber 2, to an atmospheric pressure outside the process chamber. Subsequently, into the process chamber a further gas for depletion, i.e. neutralization, of coatings in the process chamber is admitted into the process chamber. The layers are passivated. Then the process chamber can be ventilated with air or nitrogen without an unwanted reaction taking place. The process chamber is subsequently opened up to the atmosphere, i.e. the door of the process chamber to the environment is opened, while always maintaining a positive pressure in the coating source space.

This permanent positive pressure in the coating source space prevents gases, especially oxygen, from getting to and reacting with the coating source, especially the reactive target material. What is important is that the shutter closes off the coating source space and is accordingly closed, i.e. pivoted across the coating source. The coating source should also be switched off.

In one configuration of the method of the invention, the reactive coating material is an oxygen-sensitive target material, for example lithium, magnesium, calcium and/or a similarly strongly reactive material such as those mentioned above. Lithium is very reactive and reacts with many elements and compounds. It therefore has to be given special protection in order to avoid cross-contamination. This is ensured by the closed shutter which by means of a rotary and/or pivoting and/or folding/tilting movement and an additional back-and-forth movement in the direction of the coating source and by virtue of the positive pressure established in the coating source space ensures.

In another configuration of the method of the invention, as a further protective measure, an inert gas, especially nitrogen or argon, is used as a protective gas. The constant positive pressure in the coating source space closed by the shutter and the protective gas admitted has the advantage that no oxygen or air can penetrate into the coating source space behind the shutter.

In a further configuration of the method of the invention, a further gas admitted into the process chamber for depletion or neutralization of coatings in the process chamber is carbon dioxide. This prevents further reactions in the process chamber and further minimizes contamination of the coating source.

The object of the invention is also achieved by a sputtering plant of the invention according to independent device claim 6. The sputtering plant comprises a process chamber and at least one coating source space which is formed from a coating source and a shutter and is disposed within the process chamber. This sputtering plant or coating plant is suitable for performance of the method according to claims 1 to 5. It is particularly advantageous that the shutter is positionable above the coating source by means of a rotary and/or pivoting and/or folding/tilting movement and the shutter is designed to perform an additional relative movement to the coating source and/or the coating source is designed to perform an additional relative movement to the shutter, where the shutter covers the coating source in a sealing manner and, during a process of maintenance of the sputtering plant, a permanent positive pressure can be formed in the coating source space. The relative movement is advantageously a back-and-forth movement. This prevents unwanted particles, gas atoms etc. from reaching the target, i.e. getting into the coating source space. The concept is found to be particularly advantageous when the coating source space comprises a target made of an oxygen-sensitive material, for example lithium, magnesium and/or calcium.

According to the invention, the shutter is positionable above the coating source by means of a rotary and/or pivoting and/or folding/tilting movement and the shutter is designed to perform an additional relative movement to the coating source in the form of a back-and-forth movement and/or the coating source is designed to perform an additional relative movement to the shutter in the form of a back-and-forth movement, where the shutter covers the coating source in a sealing manner.

Sealing coverage is considered to mean complete shielding of the coating source from the rest of the process chamber, so as to prevent any cross contamination of the coating source and unwanted coatings on the substrate to be coated. Oxygen thus cannot get into the coating source space and contaminate the target material and cause unwanted reactions.

It is advantageous that the shutter of the sputtering plant of the invention is not only pivoted or rotated or folded/tilted over the coating source in a first degree of freedom, but the shutter or the coating source are also moved toward one another in a sealing manner in a second degree of freedom by a relative movement between shutter and coating source. Either the shutter performs a back-and-forth movement in the direction of the coating source or the coating source performs a back-and-forth movement in the direction of the shutter, such that the shutter and the coating source are positioned one on top of another in a sealing manner, i.e. in a completely closed manner. Both movements are performable independently of one another, such that the shutter is positionable in any required and desired position. There is no deflection of the gas plasma by the movements of the shutter. This does not give rise to formation of particles by friction between shutter plate and coating source, as in the case of pure pivoting of the shutter over the coating source. With the shutter closed, there is no longer any gap through which contamination of the target material can arise as a result of operation of different coating sources in the same arrangement or penetrating oxygen in the case of maintenance operations.

The shutter may be positioned above the coating source, for example, via a rotary movement about an axis or via a pivoting movement via a lateral approach relative to the coating source or via a folding/tilting movement. Only thereafter does the relative movement or back-and-forth movement take place between shutter and coating source. The rotating/pivoting/folding/tilting and/or back-and-forth movements are brought about by means of shutter movement, such as motors or lifting cylinders. The controller of the shutter system is outside the vacuum chamber, such that abrasion by mechanical components within the vacuum chamber is reduced to a minimum.

The solution proposed allows a significantly more compact arrangement of different coating sources to take place in a parallel and/or co-coating arrangement (e.g. sputtering arrangement), since cross-contamination of the coating sources is prevented. There is no longer any need for a large projection of the shutter plates.

In one configuration of the shutter system of the invention, the relative movement between shutter and coating source is formed by means of bellows or ring seals and/or linear feedthroughs. This reduces mechanical wear within the vacuum chamber to a minimum. There is no occurrence of contamination via abrasion or mechanical friction.

Relative movement between shutter and coating source is effected by means of a back-and-forth movement, which is effected either by the shutter or by the coating source. The simpler implementation in construction terms involves a movement of the shutter with a simultaneously fixed coating source.

In another configuration of the sputtering plant of the invention, a distance between coating source and shutter is formed in an adjustable manner. This has the advantage that, especially in the case of maintenance operations in the process chamber, the distance between shutter and coating source can be adjusted to zero, so as to avoid contamination of the target. A further advantage is that, at the start of the process, for ignition of the plasma in the sputtering operation, the necessary gap between coating source and shutter can be established and, in the actual coating process, in particular with multiple coating sources, the respective coating source that is not being used at that time can be optimally shielded in a sealing manner. Actuation of the shutter system of the invention makes it possible to keep the shutter in any required and desired position. This is possible by virtue of the separately controllable and independently executable movements of the shutter system.

Shielding is further optimized when, in a further configuration of the shutter system of the invention, the shutter has a folded-over edge. By virtue of the folded-over edge, the shutter acts like a kind of hood over the coating source, such that cross-contamination can be completely prevented.

In addition, the shutter and the coating source have a round or oval or rectangular or polygonal shape. It is thus possible to match the shutter to the shape of the coating source to be covered in order to optimally seal it. By virtue of the independently performable movements (rotary and/or pivoting and/or folding or tilting movement, and the additional relative movement) of the shutter, the shutter system of the sputtering plant can likewise be matched to any coating source in a very simple manner.

The method of the invention for protection of a coating source, especially a reactive, oxygen-sensitive target material, in a sputtering plant, and the sputtering plant of the invention for performance of the method of the invention, can be used for any coating source with a directed stream of particles. Effective suppression of cross-contamination of the coating source and prevention of reactions with a reactive target material is thus possible in a simple and compact manner.

The invention is to be elucidated in detail hereinafter by working examples. The accompanying drawings show:

FIG. 1 sputtering plant of the invention with a coating source (a sputtering target) in a coating source space closable with a shutter having a folded-over edge;

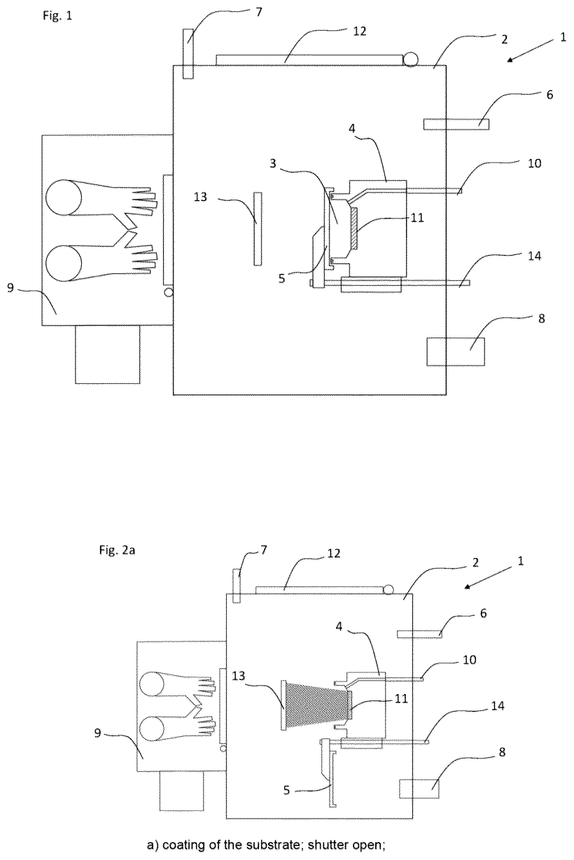

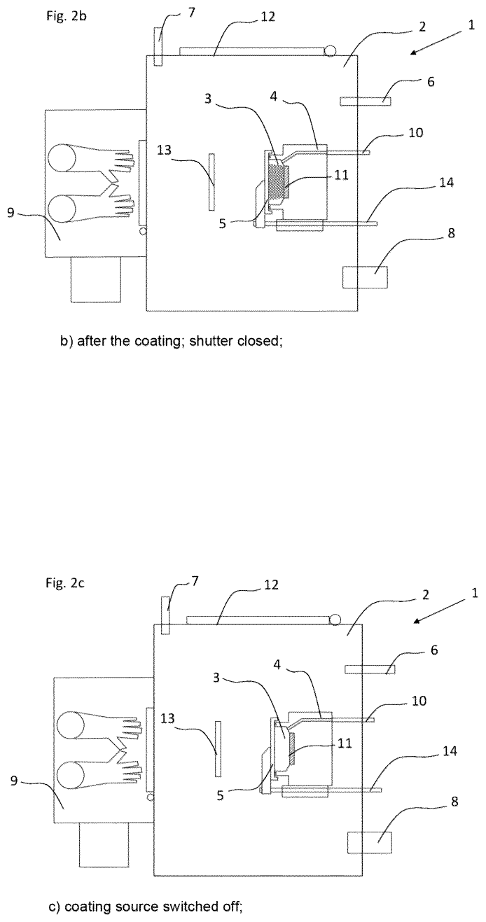

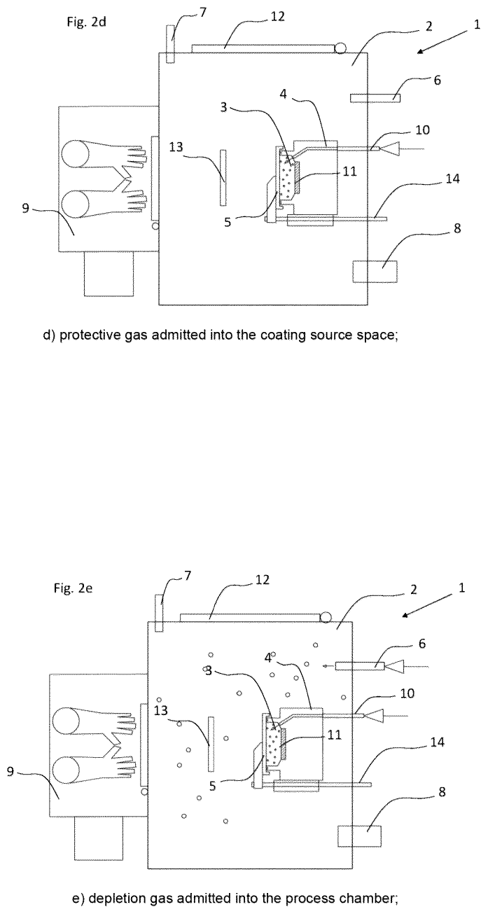

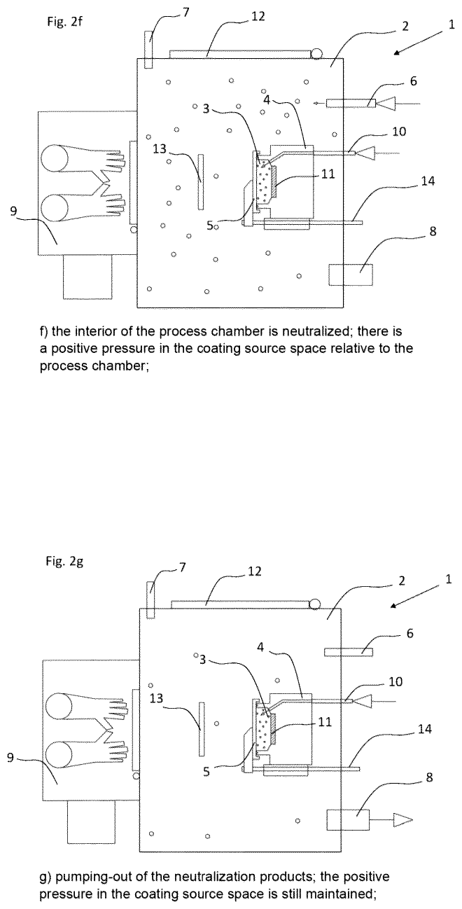

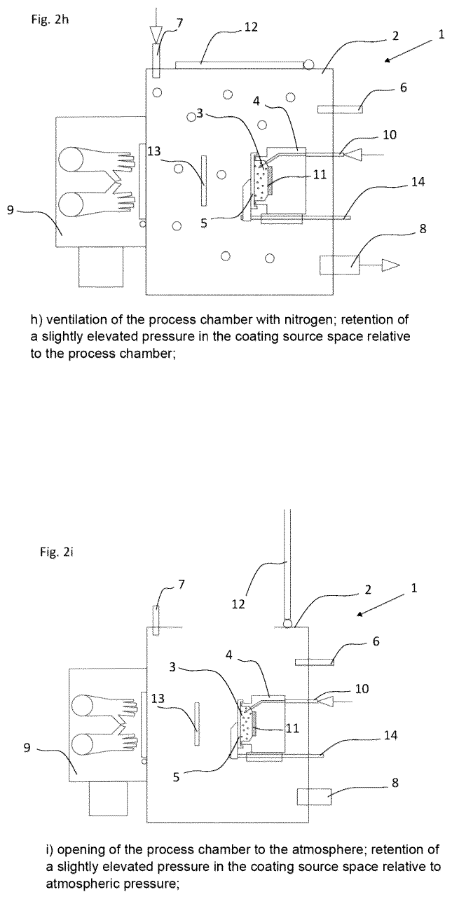

FIG. 2 schematic diagram of inventive method steps a) to i).

FIG. 1 shows a schematic diagram of the inventive sputtering plant 1, where the latter comprises a process chamber 2 in which there is at least one coating source space 3 formed from a coating source 4 and a shutter 5. The process chamber 2 also has an inlet valve 6 for a reacting gas, a ventilation valve 7 for the process chamber 2, a vacuum pump 8 and a glovebox 9 for the performance of maintenance operations or a change of substrate and/or target 11 without having to break the vacuum in the process chamber 2. The coating source space 3 additionally has an inlet 10 for a protective gas, e.g. nitrogen and/or argon. The protective gas, which is introduced into the coating source space 3 with a positive pressure relative to a vacuum chamber pressure within the process chamber 2 and, later on, in the ventilation of the process chamber 2, to an atmospheric pressure outside the process chamber 2 prevents oxygen from being able to penetrate through any residual gap into the coating source space 3.

FIG. 2 shows a schematic diagram of the method steps of the invention using the sputtering plant of the invention.

In a normal coating process, the substrate 13 to be coated is opposite the coating source 4 in the process or vacuum chamber 2. During the coating process, the coating source space 3 is open, meaning that the shutter 5 is pivoted/rotated/folded to the side, such that material is removed/sputtered from the target 11 and is deposited on the substrate surface 13. Once the coating process has ended, the shutter 5 is moved in front of the coating source 4 again in such a way that no gap exists between shutter 5 and coating source 4. This is ensured mechanically by the additional relative movement between shutter 5 and coating source 4. The controller of the shutter system 5 is outside the vacuum chamber 2, such that abrasion by mechanical components within the vacuum chamber 2 is reduced to a minimum. The coating source 4 is then switched off. Subsequently, a protective gas, e.g. nitrogen or argon, is introduced into the coating source space 3 via a gas inlet 10. Thereafter, the process chamber 2 is flooded with a depletion gas, e.g. CO₂, such that components in the vacuum chamber 2 can be depleted and the process chamber 2 is internally neutralized. A positive pressure is simultaneously generated in the coating source space 3 in order to effectively prevent penetration of particles and gases, e.g. oxygen. In a next step, the gas is pumped out of the process chamber 2 and the positive pressure in the coating source space 3 is still maintained. By means of a ventilation valve 7, in a further method step, nitrogen or another ventilation gas is guided into the process chamber 2, and a slightly elevated pressure relative to atmospheric pressure outside the process chamber 2 is still maintained in the coating source space 3. Subsequently, the process chamber 2 can be opened and necessary maintenance operations etc. can be conducted, where the constant slightly elevated pressure in the coating source space 3 completely prevents contamination of the reactive, in particular oxygen-sensitive, target materials 11.

### LIST OF REFERENCE NUMERALS

1 sputtering plant
2 process/vacuum chamber
3 coating source space
4 coating source
5 shutter
6 inlet valve for gas for the depletion process
7 ventilation valve
8 vacuum pump
9 glovebox
10 protective gas inlet
11 target
12 process chamber door
13 substrate to be coated
14 shutter movement means

1. A method of protecting a coating source comprising a reactive coating material, where the coating source comprising the coating material is shielded from a process chamber by a shutter, wherein
the shutter closes off the coating source in a sealing manner and a protective gas is admitted via a gas inlet into a coating source space which is formed by the coating source and the shutter, and a positive pressure is established in the coating source space relative to a vacuum chamber pressure within the process chamber and, later on, to an atmospheric pressure outside the process chamber,
into the process chamber a further gas for depletion of coatings in the process chamber is admitted into the process chamber,
the further gas is pumped out of the process chamber,
the process chamber is ventilated by introduction of nitrogen or another gas,
the process chamber is opened up to the atmosphere, where
a positive pressure is always maintained in the coating source space.

2. The method as claimed in claim 1, wherein the reactive coating material is an oxygen-sensitive target material.

3. The method as claimed in claim 2, wherein the target material is formed from lithium, magnesium, calcium and/or a similarly strongly reactive material.

4. The method as claimed in claim 1, wherein the protective gas is an inert gas, especially nitrogen or argon.

5. The method as claimed in claim 1, wherein the further gas admitted for depletion is especially carbon dioxide.

6. A sputtering plant comprising a process chamber and at least one coating source space which is formed from a coating source and a shutter and is disposed within the process chamber and is designed and suitable for performance of the method according to claim 1, wherein the shutter is positionable above the coating source by a rotary and/or pivoting and/or folding/tilting movement and the shutter is designed to perform an additional relative movement to the coating source and/or the coating source is designed to perform an additional relative movement to the shutter, where the shutter covers the coating source in a sealing manner and, during a process of maintenance of the sputtering plant, a permanent positive pressure can be formed in the coating source space.

7. The sputtering plant as claimed in claim 6, wherein the relative movement between shutter and coating source is implemented by bellows or ring seals and/or linear feedthroughs.

8. The sputtering plant as claimed in claim 6, wherein a distance is established in an adjustable manner between coating source and shutter.

9. The sputtering plant as claimed in claim 6, wherein the shutter has a folded-over edge.

10. The sputtering plant as claimed in claim 6, wherein the shutter and the coating source have a round or oval or rectangular or polygonal shape.
